(19) United States
(12) Patent Application Publication
(10) Pub. No.: US 2010/0123230 A1
(43) Pub. Date: May 20, 2010

(54) INTEGRATED CIRCUIT PACKAGING SYSTEM HAVING BUMPED LEAD AND METHOD OF MANUFACTURE THEREOF

(76) Inventors: Frederick Rodriguez Dahilig, Singapore (SG); Zigmund Ramirez Camacho, Singapore (SG); Henry Descalzo Bathan, Singapore (SG); Lionel Chien Hui Tay, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/275,214

(22) Filed: Nov. 20, 2008

(51) Int. Cl. H01L 23/495; H01L 21/56; H01L 21/00

(52) U.S. Cl. 257/676; 438/123; 438/109; 257/E23.037

(57) ABSTRACT

A method of manufacture of an integrated circuit packaging system includes: forming a first terminal having a cavity; mounting a first integrated circuit over the first terminal and connected in the cavity; forming a second terminal adjacent to the first terminal; connecting a second integrated circuit, over the first integrated circuit, and the second terminal; and forming a first encapsulation over the first integrated circuit with the first terminal exposed.

### CROSS-REFERENCE TO RELATED APPLICATION(S)

The present application contains subject matter related to co-pending U.S. patent application Ser. No. 12/168,803 filed Jul. 7, 2008. The related application is assigned to STATS ChipPAC Ltd. and the subject matter thereof is incorporated herein by reference thereto.

### TECHNICAL FIELD

The present invention relates generally to an integrated circuit packaging system and more particularly to an integrated circuit packaging system with a lead.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made therefrom. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Many conventional semiconductor (or “chip”) packages are of the type where a semiconductor die is molded into a package with a resin, such as an epoxy molding compound. The packages have a lead frame whose leads are projected from the package body, to provide a path for signal transfer between the die and external devices. Other conventional package configurations have contact terminals or pads formed directly on the surface of the package.

The semiconductor packages, thus manufactured, are then mounted by matching and soldering the external leads or contact pads thereof to a matching pattern on a circuit board, to thereby enable power and signal input/output (“I/O”) operations between the semiconductor devices in the packages and the circuit board.

Different challenges arise from increased functionality integration and miniaturization. For example, a semiconductor product having increased functionality may be made smaller but may still be required to provide a large number of inputs/outputs (I/O). The size reduction increases the I/O density or decreases the I/O pitch for the integrated circuit package and its respective integrated circuit carriers.

The ever-increasing I/O density trend presents a myriad of manufacturing problems. Some of these problems reside in integrated circuit manufacturing realm, such as fine pitch connections and reliability of these connections. Others problems involve mounting these increase I/O density integrated circuits on carriers for packaging. Yet other problems reside in the realm of the printed circuit board or the system board that receives the integrated circuit package having the fine pitch I/O or a large number of I/Os in an ever-shrinking space.

Thus, a need still remains for an integrated circuit packaging system providing low cost manufacturing, improved yield, improved reliability, and high density I/O count. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including forming a first terminal having a cavity; mounting a first integrated circuit over the first terminal and connected in the cavity; forming a second terminal adjacent to the first terminal; connecting a second integrated circuit, over the first integrated circuit, and the second terminal; and forming a first encapsulation over the first integrated circuit with the first terminal exposed.

The present invention provides an integrated circuit packaging system including a first terminal having a cavity; a first integrated circuit over the first terminal and connected in the cavity; a second terminal adjacent to the first terminal; a second integrated circuit over the first integrated circuit and connected to the second terminal; and a first encapsulation over the first integrated circuit with the first terminal exposed.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in a first embodiment of the present invention.

FIG. 2 is a cross-sectional view of the integrated circuit packaging system along line 2-2 of FIG. 1.

FIG. 3 is a cross-sectional view of an integrated circuit packaging system exemplified by the top view of FIG. 1 in a second embodiment of the present invention.

FIG. 4 is a top view of an integrated circuit packaging system in a third embodiment of the present invention.

FIG. 5 is a cross-sectional view of the integrated circuit packaging system along line 5-5 of FIG. 4.

FIG. 6 is a cross-sectional view of an integrated circuit packaging system exemplified by the top view of FIG. 4 in a fourth embodiment of the present invention.

FIG. 7 is a cross-sectional view of an integrated circuit packaging system exemplified by the top view of FIG. 4 in a fifth embodiment of the present invention.

FIG. 8 is a cross-sectional view of an integrated circuit packaging system exemplified by the top view of FIG. 4 in a sixth embodiment of the present invention.

FIG. 9 is a cross-sectional view of an integrated circuit packaging system exemplified by the top view of FIG. 4 in a seventh embodiment of the present invention.

FIG. 10 is a cross-sectional view of an integrated circuit packaging system exemplified by the top view of FIG. 4 in an eighth embodiment of the present invention.

FIG. 11 is a cross-sectional view of an integrated circuit packaging system exemplified by the top view of FIG. 4 in a ninth embodiment of the present invention.

FIG. 12 is a structure of a portion of a lead frame.

FIG. 13 is the structure of FIG. 12 in connecting the integrated circuit and internal interconnects.

FIG. 14 is the structure of FIG. 14 in forming an encapsulation.

FIG. 15 is the structure of FIG. 14 in forming the integrated circuit packaging system of FIG. 5.

FIG. 16 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Generally, the invention can be operated in any orientation.

In addition, where multiple embodiments are disclosed and described having some features in common, for clarity and ease of illustration, description, and comprehension thereof, similar and like features one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane.

The term “on” means there is direct contact among elements. The term “processing” as used herein includes deposition of material, patterning, exposure, development, etching, cleaning, molding, and/or removal of the material or as required in forming a described structure.

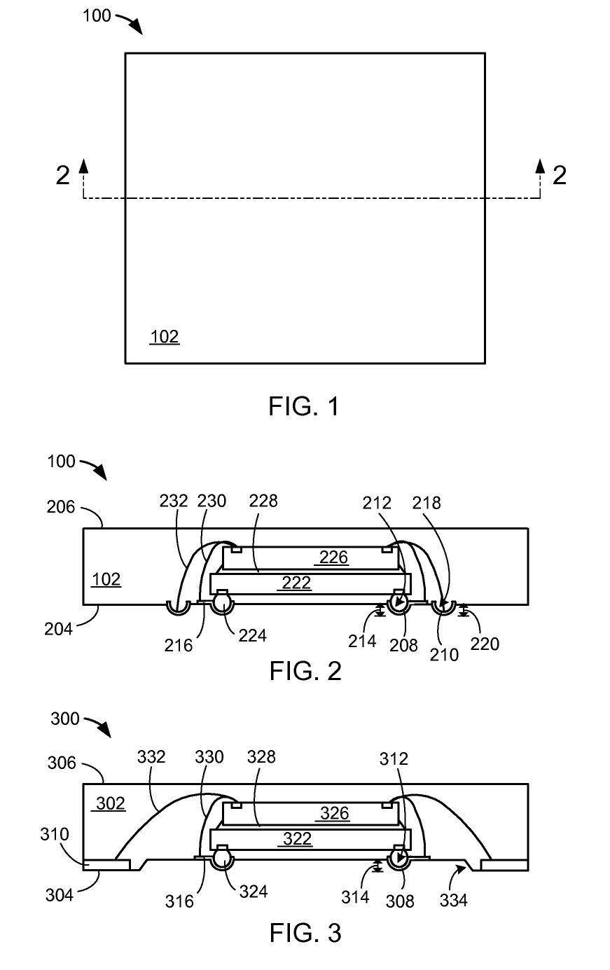

Referring now to FIG. 1, therein is shown a top view of an integrated circuit packaging system 100 in a first embodiment of the present invention. The top view depicts an encapsulation 102, such as a cover with an epoxy molding compound. For illustrative purposes, the integrated circuit packaging system 100 is shown with a square geometric shape, although it is understood that the shape of the integrated circuit packaging system 100 may be different, such as rectangular or a geometric shape that is not a square.

Referring now to FIG. 2, therein is shown a cross-sectional view of the integrated circuit packaging system 100 along line 2-2 of FIG. 1. The integrated circuit packaging system 100 includes the encapsulation 102 having a first encapsulation side 204 intersecting one of the non-horizontal sides and a second encapsulation side 206 on an opposing side of the first encapsulation side 204.

The first encapsulation side 204 includes first terminals 208, such as plated bumps, and second terminals 210, such as plated bump. Each of the first terminals 208 can include a first cavity 212, having a first height 214 from the first encapsulation side 204. Each of the first terminals 208 can also include a first extension 216 at the periphery of the first terminals 208.

The second terminals 210 can be adjacent to the first terminals 208. The second terminals 210 can be between the first terminals 208 and a periphery of the integrated circuit packaging system 100. Each of the second terminals 210 can include a second cavity 218, having a second height 220 from the first encapsulation side 204. The second cavity 218 can be filled with the encapsulation 102.

A first integrated circuit 222, such as a flip chip or a ball grid array packaged integrated circuit, can be over the first terminals 208 with first electrical connectors 224, such as solder bumps, of the first integrated circuit 222. The first electrical connectors 224 are shown at a periphery of the first integrated circuit 222. The first integrated circuit 222 can be over the first terminals 208 with the first electrical connectors 224 attached within the first cavity 212 of the first terminals 208.

A second integrated circuit 226, such as an integrated circuit die or a packaged integrated circuit, can be over the first integrated circuit 222 with an adhesive 228, such as a die-attach adhesive. First internal interconnects 230, such as bond wires, ribbon bond wires, or reverse standoff stitch bonding (RSSB), can connect the second integrated circuit 226 and the first extension 216. Second internal interconnects 232, such as bond wires, ribbon bond wires, or reverse standoff stitch bonding (RSSB), can connect the second integrated circuit 226 and the second terminals 210 within the second cavity 218.

The encapsulation 102 can cover the first integrated circuit 222, the second integrated circuit 226, the first internal interconnects 230, the second internal interconnects 232, and the second cavity 218. For example, the first terminals 208, and the second terminals 210, can be formed in a U-shaped terminal in a non-planar configuration extending below the first encapsulation side 204. For illustrative purposes, the first terminals 208, and the second terminals 210 are shown as U-shaped terminals, although it is understood that it can be of different geometric shapes, such as rectangular, triangular, or circular shapes.

For illustrative purposes, the integrated circuit packaging system 100 is shown with the first internal interconnects 230 and the second internal interconnects 232 connecting to the same connection of the second integrated circuit 226, although it is understood that the integrated circuit packaging system 100 can have different connections. For example, the first internal interconnects 230 and the second internal interconnects 232 can connect to different portions of the second integrated circuit 226.

Referring now to FIG. 3, therein is shown a cross-sectional view of an integrated circuit packaging system 300 exemplified by the top view of FIG. 1 in a second embodiment of the present invention. The integrated circuit packaging system 300 includes an encapsulation 302, such as a cover with an epoxy molding compound, having a first encapsulation side 304 intersecting one of the non-horizontal sides. A second encapsulation side 306 is on an opposing side of the first encapsulation side 304.

Second terminals 310, such as leads, is at a periphery of the encapsulation 302 and partially exposed by the first encapsulation side 304. The first encapsulation side 304 is non-planar and forms a recess 334, partially exposing first terminals 308, such as plated bumps.

Each of the first terminals 308 can include a first cavity 312, having a first height 314 from the first encapsulation side 304. Each of the first terminals 308 can also include a first extension 316 at the periphery of the first terminals 308.

A first integrated circuit 322, such as a flip chip or a ball grid array packaged integrated circuit, is over the first terminals 308 with first electrical connectors 324, such as solder bumps, of the first integrated circuit 322. The first electrical connectors 324 are shown at a periphery of the first integrated circuit 322. The first integrated circuit 322 can be over the first terminals 308 with the first electrical connectors 324 attached within the first cavity 312 of the first terminals 308.

A second integrated circuit 326, such as an integrated circuit die or a flip chip, can be over the first integrated circuit 322 with an adhesive 328, such as a die-attach adhesive. First internal interconnects 330, such as bond wires, ribbon bond wires, or reverse standoff stitch bonding (RSSB), can be between the second integrated circuit 326 and the first extension 316. Second internal interconnects 332, such as bond wires, ribbon bond wires, or reverse standoff stitch bonding (RSSB), can be between the second integrated circuit 326 and the second terminals 310.

The encapsulation 302 can cover the first integrated circuit 322, the second integrated circuit 326, the first internal interconnects 330, and the second internal interconnects 332. The encapsulation 302 partially exposes the second terminals 310 and the first terminals 308. For example, the first terminals 308 can be formed in a U-shaped terminal in a non-planar configuration extending below the first encapsulation side 304 and within the recess 334 of the encapsulation 302. For illustrative purposes, the first terminals 308 are shown as U-shaped terminals, although it is understood that it can be of different geometric shapes, such as rectangular, triangular, or circular shapes.

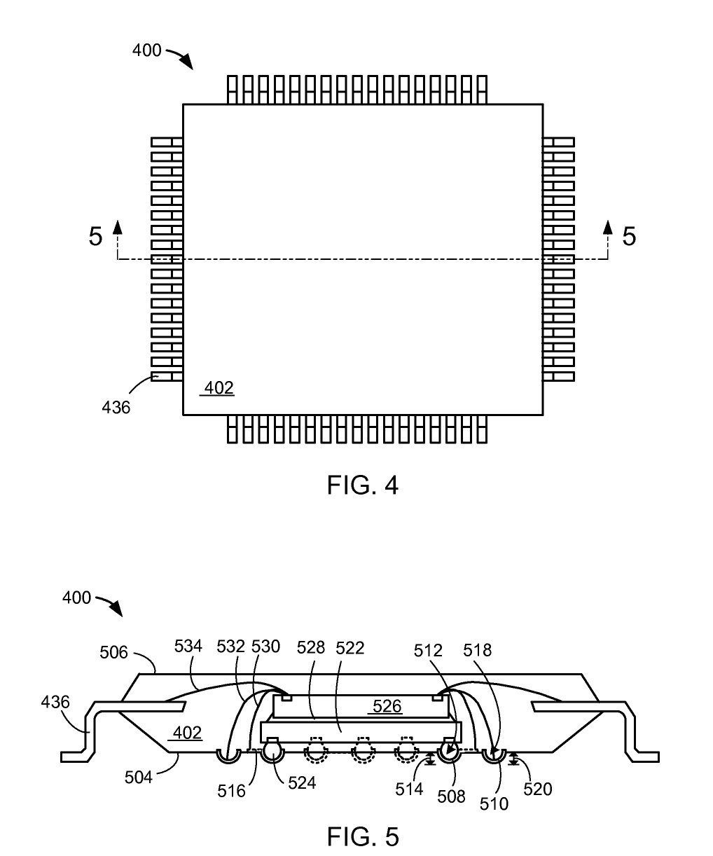

Referring now to FIG. 4, therein is shown a top view of an integrated circuit packaging system 400 in a third embodiment of the present invention. The top view depicts an encapsulation 402, such as a cover with an epoxy molding compound, with leads 436 partially exposed and extending peripherally from the encapsulation 402. For example, the leads 436 may be for the integrated circuit packaging system 400 of a quad flat package type.

For illustrative purposes, the integrated circuit packaging system 400 is shown with a square geometric configuration, although it is understood that the integrated circuit packaging system 400 can be formed in a different geometric configuration. For example, the integrated circuit packaging system 400 can have a rectangular configuration.

Referring now to FIG. 5, therein is shown a cross-sectional view of the integrated circuit packaging system 400 along line 5-5 of FIG. 4. The cross-sectional view depicts the encapsulation 402 having the leads 436 extending from the non-horizontal sides of the encapsulation 402. The encapsulation 402 includes a first encapsulation side 504 intersecting one of the non-horizontal sides, and a second encapsulation side 506 on an opposing side of the first encapsulation side 504.

The first encapsulation side 504 includes an array of first terminals 508, such as plated bumps, and second terminals 510, such as plated bump. Each of the first terminals 508 can include a first cavity 512, having a first height 514 from the first encapsulation side 504. Each of the first terminals 508 at the periphery of the array can also include a first extension 516. An interior portion of the array can be optional, as depicted by dotted arches.

The second terminals 510 can be adjacent to the array of the first terminals 508. The second terminals 510 can be between the array of the first terminals 508 and the leads 436. Each of the second terminals 510 can include a second cavity 518, having a second height 520 from the first encapsulation side 504. The second cavity 518 can be filled with the encapsulation 402.

A first integrated circuit 522, such as a flip chip or a ball grid array packaged integrated circuit, having first electrical connectors 524, such as solder bumps, can be over the first terminals 508. The first integrated circuit 522 can be over the first terminals 508 with the first electrical connectors 524 attached within the first cavity 512.

As shown by dotted lines, the integrated circuit packaging system 400 can optionally include an array of the first terminals 508. The first terminals 508, as an example, may not be an array and can be at the periphery of the first integrated circuit 522.

A second integrated circuit 526, such as an integrated circuit die or a flip chip, can be over the first integrated circuit 522 with an adhesive 528, such as a die-attach adhesive. First internal interconnects 530, such as bond wires, ribbon bond wires, or reverse standoff stitch bonding (RSSB), can be between the second integrated circuit 526 and the first extension 516 of the first terminals 508. Second internal interconnects 532, such as bond wires, ribbon bond wires, or reverse standoff stitch bonding (RSSB), can be between the second integrated circuit 526 and the second terminals 510 within the second cavity 518. Third internal interconnects 534, such as bond wires, ribbon bond wires, or reverse standoff stitch bonding (RSSB), can be between the second integrated circuit 526 and the leads 436.

The encapsulation 402 can cover the first integrated circuit 522, the second integrated circuit 526, the first internal interconnects 530, the second internal interconnects 532, the third internal interconnects 534, and fill the second cavity 518. For example, the first terminals 508, and the second terminals 510, can be formed in a U-shaped terminal in a non-planar configuration extending below the first encapsulation side 504. For illustrative purposes, the first terminals 508, and the second terminals 510 are shown as U-shaped terminals, although it is understood that it can be of different geometric shapes, such as rectangular, triangular, or circular shapes.

The leads 436 can extend from the non-horizontal sides of the encapsulation 402 and provide mounting to the next system levels (not shown), such as printed circuit board or a further integrated circuit packaging system. As an example, the leads 436 are shown bending towards the first encapsulation side 504. As a different example (not shown), the leads 436 can bend towards the second encapsulation side 506. Both the first encapsulation side 504 and the second encapsulation side 506 are horizontal sides of the encapsulation 402.

For illustrative purposes, the integrated circuit packaging system 400 is shown with the first internal interconnects 530, the second internal interconnects 532, and the third internal interconnects 534 connecting to the same connection of the second integrated circuit 526, although it is understood that the integrated circuit packaging system 400 can have different connections. For example, the first internal interconnects 530, the second internal interconnects 532, and the third internal interconnects 534 can connect to different portions of the second integrated circuit 526.

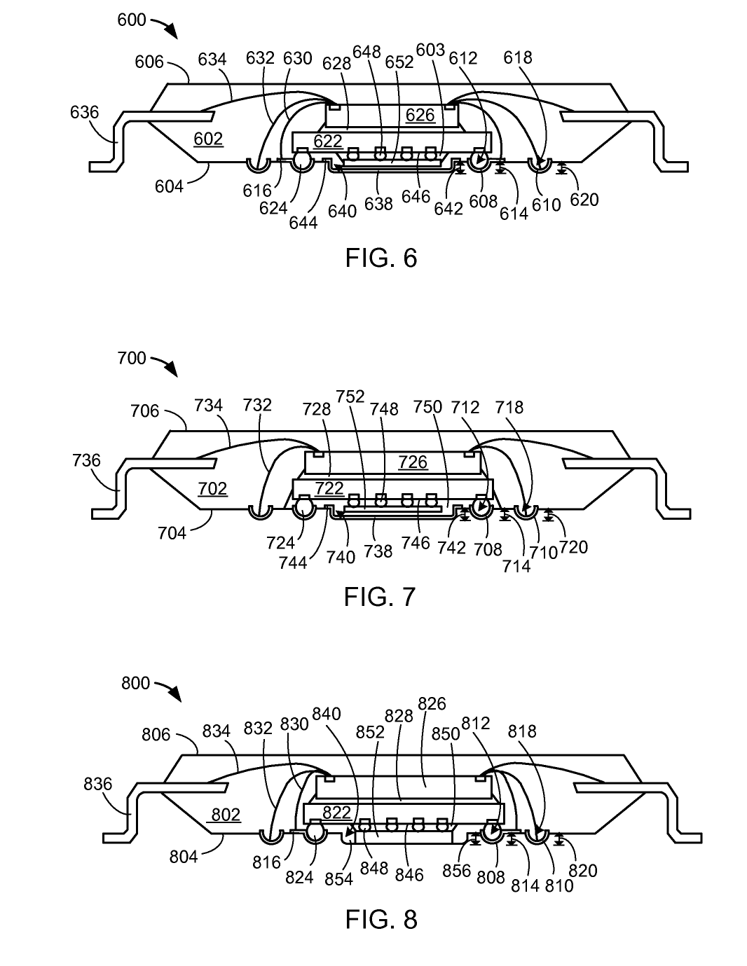

Referring now to FIG. 6, therein is shown a cross-sectional view of an integrated circuit packaging system 600 exemplified by the top view of FIG. 4 in a fourth embodiment of the present invention. The cross-sectional view depicts an encapsulation 602, such as a cover with an epoxy molding compound, having leads 636 extending from the non-horizontal sides of the encapsulation 602. The encapsulation 602 includes a first encapsulation side 604 intersecting one of the non-horizontal sides, and a second encapsulation side 606 on an opposing side of the first encapsulation side 604.

The first encapsulation side 604 includes bump paddle 638, such as plated bump, first terminals 608, and second terminals 610. The bump paddle 638 can include a paddle cavity 640, having a paddle height 642 from the first encapsulation side 604. The bump paddle 638 can also include a paddle extension 644 at the periphery of the bump paddle 638.

The first terminals 608, such as plated bumps, can be between the second terminals 610, such as plated bumps, and the bump paddle 638. Each of the first terminals 608 can include a first cavity 612, having a first height 614 from the first encapsulation side 604. The first terminals 608 can also include a first extension 616 at the periphery of the first terminals 608. Each of the second terminals 610 can include a second cavity 618, having a second height 620 from the first encapsulation side 604. The second cavity 618 can be filled with the encapsulation 602.

A first integrated circuit 622, such as a flip chip or a ball grid array packaged integrated circuit, is over the first encapsulation side 604, with first electrical connectors 624, such as solder bumps, of the first integrated circuit 622. The first electrical connectors 624 are shown at a periphery of the first integrated circuit 622. The first integrated circuit 622 is mounted over the first terminals 608 with the first electrical connectors 624 attached within the first cavity 612 of the first terminals 608.

The first integrated circuit 622 includes an active side 646 having active circuitry fabricated thereon. The active side 646 faces the first encapsulation side 604. The first integrated circuit 622 can also be attached to second electrical connectors 648, such as solder bumps. The second electrical connectors 648 are at an interior portion on the active side 646. The second electrical connectors 648 are smaller in size than the first electrical connectors 624.

A second integrated circuit 626, such as an integrated circuit die or a packaged integrated circuit, can be over the first integrated circuit 622 with an adhesive 628, such as a die-attached adhesive. First internal interconnects 630, such as bond wires, ribbon bond wires, or reverse standoff stitch bonding (RSSB), can be between the second integrated circuit 626 and the first extension 616. Second internal interconnects 632, such as bond wires, ribbon bond wires, or reverse standoff stitch bonding (RSSB), can be between the second integrated circuit 626 and the second terminals 610. Third internal interconnects 634, such as bond wires, ribbon bond wires, or reverse standoff stitch bonding (RSSB), can be between the second integrated circuit 626 and the leads 636.

A device 652, such as an integrated circuit die or a flip chip, can be under the first integrated circuit 622 and within the paddle cavity 640 of the bump paddle 638. The first integrated circuit 622 can be attached to the second electrical connectors 648 of the device 652. A second encapsulation 603, such as an underfill, can surround and provide structural support to the second electrical connectors 648.

The leads 636 can extend from the non-horizontal sides of the encapsulation 602. As an example, the leads 636 are shown bending towards the first encapsulation side 604. As a different example (not shown), the leads 636 can bend towards the second encapsulation side 606.

The encapsulation 602 can cover the first integrated circuit 622, the second integrated circuit 626, the device 652, the first internal interconnects 630, the second internal interconnects 632, and the third internal interconnects 634. The first encapsulation side 604 can expose the bump paddle 638, the first terminals 608, and the second terminals 610. For example, the bump paddle 638, the first terminals 608, and the second terminals 610 can be formed in a U-shaped terminal in a non-planar configuration extending below the first encapsulation side 604. For illustrative purposes, the bump paddle 638, the first terminals 608, and the second terminals 610 are shown as U-shaped terminals, although it is understood that it can be of different geometric shapes, such as rectangular, triangular, or circular shapes.

Referring now to FIG. 7, therein is shown a cross-sectional view of an integrated circuit packaging system 700 exemplified by the top view of FIG. 4 in a fifth embodiment of the present invention. The cross-sectional view depicts an encapsulation 702, such as a cover with an epoxy molding compound, having leads 736 extending from the non-horizontal sides of the encapsulation 702. The encapsulation 702 includes a first encapsulation side 704 intersecting one of the non-horizontal sides, and a second encapsulation side 706 on an opposing side of the first encapsulation side 704.

The first encapsulation side 704 includes bump paddle 738, such as plated bump, first terminals 708, and second terminals 710. The bump paddle 738 can include a paddle cavity 740, having a paddle height 742 from the first encapsulation side 704. The bump paddle 738 can also include a paddle extension 744 at the periphery of the bump paddle 738.

The first terminals 708, such as plated bumps, can be between the second terminals 710, such as plated bumps, and the bump paddle 738. Each of the first terminals 708 can include a first cavity 712, having a first height 714 from the first encapsulation side 704. Each of the second terminals 710 can include a second cavity 718, having a second height 720 from the first encapsulation side 704. The second cavity 718 can be filled with the encapsulation 702.

A first integrated circuit 722, such as a flip chip or a ball grid array packaged integrated circuit, is over the first encapsulation side 704, with first electrical connectors 724, such as solder bumps. The first electrical connectors 724 are shown at a periphery of the first integrated circuit 722. The first integrated circuit 722 can be over the first terminals 708 with the first electrical connectors 724 attached within the first cavity 712 of the first terminals 708.

The first integrated circuit 722 includes an active side 746 having active circuitry fabricated thereon. The active side 746 faces the first encapsulation side 704. The first integrated circuit 722 can also be attached to second electrical connectors 748, such as solder bumps. The second electrical connectors 748 are at an interior portion on the active side 746. The second electrical connectors 748 are smaller in size than the first electrical connectors 724.

A second integrated circuit 726, such as an integrated circuit die or a packaged integrated circuit, can be over the first integrated circuit 722 with an adhesive 728, such as a die-attached adhesive. Second internal interconnects 732, such as bond wires, ribbon bond wires, or reverse standoff stitch bonding (RSSB), can be between the second integrated circuit 726 and the second terminals 710. Third internal interconnects 734, such as bond wires, ribbon bond wires, or reverse standoff stitch bonding (RSSB), can be between the second integrated circuit 726 and the leads 736.

A device 752, such as an integrated circuit die or a flip chip, can be under the first integrated circuit 722 and within the paddle cavity 740 of the bump paddle 738. The first integrated circuit 722 can be attached to the second electrical connectors 748 of the device 752.

A second encapsulation 750, such as an underfill, can surround and provide structural support to the second electrical connectors 748. The second encapsulation 750 can also surround and provide structural support for the first electrical connectors 724. The second encapsulation 750 can partially fill the paddle cavity 740.

The leads 736 can extend from the non-horizontal sides of the encapsulation 702. As an example, the leads 736 are shown bending toward the first encapsulation side 704.

The encapsulation 702 can cover the first integrated circuit 722, the second integrated circuit 726, the second internal interconnects 732, and the third internal interconnects 734. The encapsulation 702 on the first encapsulation side 704 partially exposes the bump paddle 738, the first terminals 708, and the second terminals 710. For example, the bump paddle 738, the first terminals 708, and the second terminals 710 can be formed in a U-shaped terminal in a non-planar configuration extending below the first encapsulation side 704. For illustrative purposes, the bump paddle 738, the first terminals 708 and the second terminals 710 are shown as U-shaped terminals, although it is understood that it can be of different geometric shapes, such as rectangular, triangular, or circular shapes.

Referring now to FIG. 8, therein is shown a cross-sectional view of an integrated circuit packaging system 800 exemplified by the top view of FIG. 4 in a sixth embodiment of the present invention. The cross-sectional view depicts an encapsulation 802, such as a cover with an epoxy molding compound, having leads 836 extending from the non-horizontal sides of the encapsulation 802.

The encapsulation 802 includes a first encapsulation side 804 intersecting one of the non-horizontal sides, and a second encapsulation side 806 on an opposing side of the first encapsulation side 804. The first encapsulation side 804 includes a protrusion 854, first terminals 808, and second terminals 810. The protrusion 854 can have a protrusion height 856 from the first encapsulation side 804.

The first terminals 808, such as plated bumps, can be between the second terminals 810, such as plated bumps, and the protrusion 854. Each of the first terminals 808 can include a first cavity 812, having a first height 814 from the first encapsulation side 804. The first terminals 808 can also include a first extension 816 at the periphery of the first terminals 808. Each of the second terminals 810 can include a second cavity 818, having a second height 820 from the first encapsulation side 804. The second cavity 818 can be filled with the encapsulation 802.

A first integrated circuit 822, such as a flip chip or a ball grid array packaged integrated circuit, is over the first encapsulation side 804, with first electrical connectors 824, such as solder bumps, of the first integrated circuit 822. The first electrical connectors 824 are shown at a periphery of the first integrated circuit 822. The first integrated circuit 822 is mounted over the first terminals 808 with the first electrical connectors 824 attached within the first cavity 812 of the first terminals 808.

The first integrated circuit 822 includes an active side 846 having active circuitry fabricated thereon. The active side 846 faces the first encapsulation side 804. The first integrated circuit 822 can also be attached second electrical connectors 848, such as solder bumps. The second electrical connectors 848 are at an interior portion on the active side 846. The second electrical connectors 848 are smaller in size than the first electrical connectors 824.

A second integrated circuit 826, such as an integrated circuit die or a packaged integrated circuit, can be over the first integrated circuit 822 with an adhesive 828, such as a die-attached adhesive. First internal interconnects 830, such as bond wires, ribbon bond wires, or reverse standoff stitch bonding (RSSB), can be between the second integrated circuit 826 and the first extension 816. Second internal interconnects 832, such as bond wires, ribbon bond wires, or reverse standoff stitch bonding (RSSB), can be between the second integrated circuit 826 and the second terminals 810. Third internal interconnects 834, such as bond wires, ribbon bond wires, or reverse standoff stitch bonding (RSSB), can be between the second integrated circuit 826 and the leads 836.

A device 852, such as an integrated circuit die or a flip chip, can be under the first integrated circuit 822 and within a paddle cavity 840 of the protrusion 854. The first integrated circuit 822 can be attached to the second electrical connectors 848 of the device 852. The device 852 can be exposed at the protrusion 854. A second encapsulation 850, such as an underfill, can surround and provide structural support to the second electrical connectors 848.

The leads 836 can extend from the non-horizontal sides of the encapsulation 802. As an example, the leads 836 are shown bending towards the first encapsulation side 804. As a different example (not shown), the leads 836 can bend towards the second encapsulation side 806.

The encapsulation 802 can cover the first integrated circuit 822, the second integrated circuit 826, the device 852, the first internal interconnects 830, the second internal interconnects 832, and the third internal interconnects 834. The first encapsulation side 804 can expose the protrusion 854, the first terminals 808, and the second terminals 810. For example, the protrusion 854, the first terminals 808, and the second terminals 810 can be formed in a U-shaped terminal in a non-planar configuration extending below the first encapsulation side 804. For illustrative purposes, the protrusion 854, the first terminals 808, and the second terminals 810 are shown as U-shaped terminals, although it is understood that it can be of different geometric shapes, such as rectangular, triangular, or circular shapes.

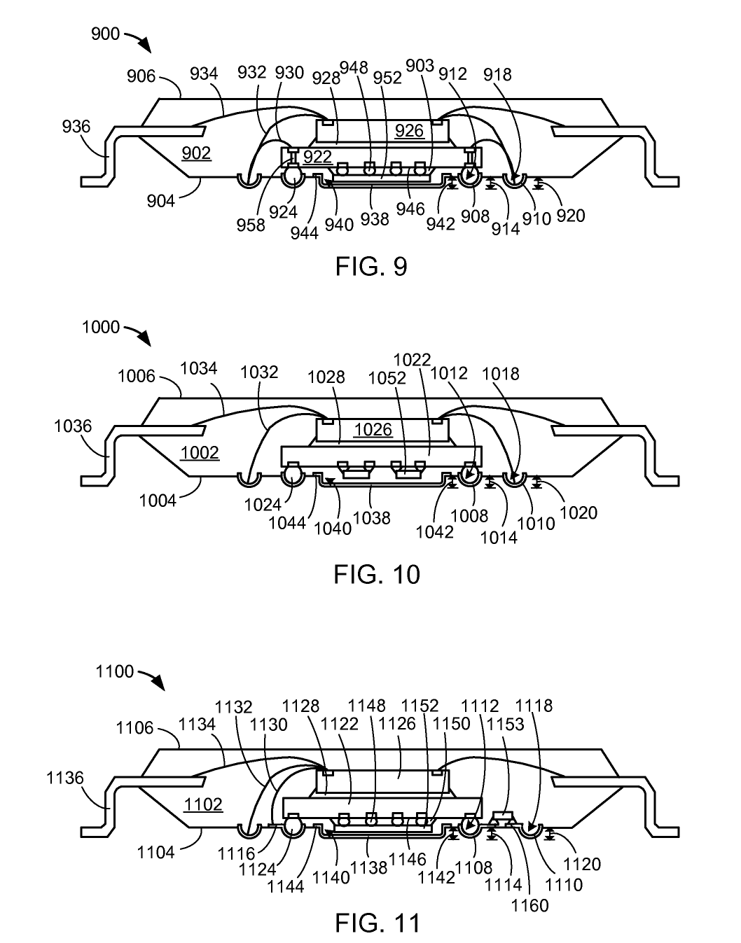

Referring now to FIG. 9, therein is shown a cross-sectional view of an integrated circuit packaging system 900 exemplified by the top view of FIG. 4 in a seventh embodiment of the present invention. The cross-sectional view depicts an encapsulation 902, such as a cover with an epoxy molding compound, having leads 936 extending from the non-horizontal sides of the encapsulation 902. The encapsulation 902 includes a first encapsulation side 904 intersecting one of the non-horizontal sides, and a second encapsulation side 906 on an opposing side of the first encapsulation side 904.

The first encapsulation side 904 includes bump paddle 938, such as plated bump, first terminals 908, and second terminals 910. The bump paddle 938 can include a paddle cavity 940, having a paddle height 942 from the first encapsulation side 904. The bump paddle 938 can also include a paddle extension 944 at the periphery of the bump paddle 938.

The first terminals 908, such as plated bumps, can be between the second terminals 910, such as plated bumps, and the bump paddle 938. Each of the first terminals 908 can include a first cavity 912, having a first height 914 from the first encapsulation side 904. Each of the second terminals 910 can include a second cavity 918, having a second height 920 from the first encapsulation side 904. The second cavity 918 can be filled with the encapsulation 902.

A first integrated circuit 922, such as a flip chip or a ball grid array packaged integrated circuit, is over the first encapsulation side 904, with first electrical connectors 924, such as solder bumps, of the first integrated circuit 922. The first electrical connectors 924 are shown at a periphery of the first integrated circuit 922 and can attached to channels 958, such as through silicon vias (TSV). The channels 958 can traverse the thickness of the first integrated circuit 922.

The first integrated circuit 922 can be over the first terminals 908 with the first electrical connectors 924 attached within the first cavity 912 of the first terminals 908. The first electrical connectors 924 can connect to the channels 958.

The first integrated circuit 922 includes an active side 946 having active circuitry fabricated thereon. The active side 946 faces the first encapsulation side 904. The first integrated circuit 922 can also be attached second electrical connectors 948, such as solder bumps. The second electrical connectors 948 are at an interior portion on the active side 946. The second electrical connectors 948 are smaller in size than the first electrical connectors 924.

A second integrated circuit 926, such as an integrated circuit die or a packaged integrated circuit, can be over the first integrated circuit 922 with an adhesive 928, such as a die-attached adhesive. First internal interconnects 930, such as bond wires, ribbon bond wires, or reverse standoff stitch bonding (RSSB), can be between the channels 958 and the second terminals 910 within the second cavity 918.

Second internal interconnects 932, such as bond wires, ribbon bond wires, or reverse standoff stitch bonding (RSSB), can be between the second integrated circuit 926 and the second terminals 910. Third internal interconnects 934, such as bond wires, ribbon bond wires, or reverse standoff stitch bonding (RSSB), can be between the second integrated circuit 926 and the leads 936.

A device 952, such as an integrated circuit die or a flip chip, can be under the first integrated circuit 922 and within the paddle cavity 940 of the bump paddle 938. The first integrated circuit 922 can be attached to the second electrical connectors 948 of the device 952. A second encapsulation 950, such as an underfill, can surround and provide structural support to the second electrical connectors 948.

The leads 936 can extend from the non-horizontal sides of the encapsulation 902. As an example, the leads 936 are shown bending towards the first encapsulation side 904. As a different example (not shown), the leads 936 can bend towards the second encapsulation side 906.

The encapsulation 902 can cover the first integrated circuit 922, the second integrated circuit 926, the device 952, the first internal interconnects 930, the second internal interconnects 932, and the third internal interconnects 934. The first encapsulation side 904 can expose the bump paddle 938, the first terminals 908, and the second terminals 910. For example, the bump paddle 938, the first terminals 908, and the second terminals 910 can be formed in a U-shaped terminal in a non-planar configuration extending below the first encapsulation side 904. For illustrative purposes, the bump paddle 938, the first terminals 908, and the second terminals 910 are shown as U-shaped terminals, although it is understood that it can be of different geometric shapes, such as rectangular, triangular, or circular shapes.

Referring now to FIG. 10, therein is shown a cross-sectional view of an integrated circuit packaging system 1000 exemplified by the top view of FIG. 4 in an eighth embodiment of the present invention. The cross-sectional view depicts an encapsulation 1002, such as a cover with an epoxy molding compound, having leads 1036 extending from the non-horizontal sides of the encapsulation 1002. The encapsulation 1002 includes a first encapsulation side 1004 intersecting one of the non-horizontal sides, and a second encapsulation side 1006 on an opposing side of the first encapsulation side 1004.

The first encapsulation side 1004 includes bump paddle 1038, such as plated bump, first terminals 1008, and second terminals 1010. The bump paddle 1038 can include a paddle cavity 1040, having a paddle height 1042 from the first encapsulation side 1004. The bump paddle 1038 can also include a paddle extension 1044 at the periphery of the bump paddle 1038.

The first terminals 1008, such as plated bumps, can be between the second terminals 1010, such as plated bumps, and the bump paddle 1038. Each of the first terminals 1008 can include a first cavity 1012, having a first height 1014 from the first encapsulation side 1004. Each of the second terminals 1010 can include a second cavity 1018, having a second height 1020 from the first encapsulation side 1004. The second cavity 1018 can be filled with the encapsulation 1002.

A first integrated circuit 1022, such as a flip chip or a ball grid array packaged integrated circuit, is over the first encapsulation side 1004, with first electrical connectors 1024, such as solder bumps. The first electrical connectors 1024 are shown at a periphery of the first integrated circuit 1022. The first integrated circuit 1022 can be over the first terminals 1008 with the first electrical connectors 1024 attached within the first cavity 1012 of the first terminals 1008.

A second integrated circuit 1026, such as an integrated circuit die or a packaged integrated circuit, can be over the first integrated circuit 1022 with an adhesive 1028, such as a die-attached adhesive. Second internal interconnects 1032, such as bond wires, ribbon bond wires, or reverse standoff stitch bonding (RSSB), can be between the second integrated circuit 1026 and the second terminals 1010. Third internal interconnects 1034, such as bond wires, ribbon bond wires, or reverse standoff stitch bonding (RSSB), can be between the second integrated circuit 1026 and the leads 1036.

Devices 1052, such as passive components or discrete components, can be under the first integrated circuit 1022 and within the paddle cavity 1040 of the bump paddle 1038. The devices can be attached to the first integrated circuit 1022.

The leads 1036 can extend from the non-horizontal sides of the encapsulation 1002. As an example, the leads 1036 are shown bending toward the first encapsulation side 1004.

The encapsulation 1002 can cover the first integrated circuit 1022, the second integrated circuit 1026, the devices 1052, the second internal interconnects 1032, and the third internal interconnects 1034. The encapsulation 1002 on the first encapsulation side 1004 partially exposes the bump paddle 1038, the first terminals 1008, and the second terminals 1010. For example, the bump paddle 1038, the first terminals 1008, and the second terminals 1010 can be formed in a U-shaped terminal in a non-planar configuration extending below the first encapsulation side 1004. For illustrative purposes, the bump paddle 1038, the first terminals 1008 and the second terminals 1010 are shown as U-shaped terminals, although it is understood that it can be of different geometric shapes, such as rectangular, triangular, or circular shapes.

Referring now to FIG. 11, therein is shown a cross-sectional view of an integrated circuit packaging system 1100 exemplified by the top view of FIG. 4 in a ninth embodiment of the present invention. The cross-sectional view depicts an encapsulation 1102, such as a cover with an epoxy molding compound, having leads 1136 extending from the non-horizontal sides of the encapsulation 1102. The encapsulation 1102 includes a first encapsulation side 1104 intersecting one of the non-horizontal sides, and a second encapsulation side 1106 on an opposing side of the first encapsulation side 1104.

The first encapsulation side 1104 includes bump paddle 1138, such as plated bump, first terminals 1108, and second terminals 1110. The bump paddle 1138 can include a paddle cavity 1140, having a paddle height 1142 from the first encapsulation side 1104. The bump paddle 1138 can also include a paddle extension 1144 at the periphery of the bump paddle 1138.

The first terminals 1108, such as plated bumps, can be between the second terminals 1110, such as plated bumps, and the bump paddle 1138. Each of the first terminals 1108 can include a first cavity 1112, having a first height 1114 from the first encapsulation side 1104. The first terminals 1108 can also include a first extension 1116 at the periphery of the first terminals 1108.

Each of the second terminals 1110 can include a second cavity 1118, having a second height 1120 from the first encapsulation side 1104. The second cavity 1118 can be filled with the encapsulation 1102. The second terminals 1110 can also optionally include a second extension 1160 at the periphery of the second terminals 1110.

A first integrated circuit 1122, such as a flip chip or a ball grid array packaged integrated circuit, is over the first encapsulation side 1104, with first electrical connectors 1124, such as solder bumps, of the first integrated circuit 1122. The first electrical connectors 1124 are shown at a periphery of the first integrated circuit 1122. The first integrated circuit 1122 is mounted over the first terminals 1108 with the first electrical connectors 1124 attached within the first cavity 1112 of the first terminals 1108.

The first integrated circuit 1122 includes an active side 1146 having active circuitry fabricated thereon. The active side 1146 faces the first encapsulation side 1104. The first integrated circuit 1122 can also be attached second electrical connectors 1148, such as solder bumps. The second electrical connectors 1148 are at an interior portion on the active side 1146. The second electrical connectors 1148 are smaller in size than the first electrical connectors 1124.

A second integrated circuit 1126, such as an integrated circuit die or a packaged integrated circuit, can be over the first integrated circuit 1122 with an adhesive 1128, such as a die-attached adhesive. First internal interconnects 1130, such as bond wires, ribbon bond wires, or reverse standoff stitch bonding (RSSB), can be between the second integrated circuit 1126 and the first extension 1116. Second internal interconnects 1132, such as bond wires, ribbon bond wires, or reverse standoff stitch bonding (RSSB), can be between the second integrated circuit 1126 and the second terminals 1110. Third internal interconnects 1134, such as bond wires, ribbon bond wires, or reverse standoff stitch bonding (RSSB), can be between the second integrated circuit 1126 and the leads 1136.

A first device 1152, such as an integrated circuit die or a flip chip, can be under the first integrated circuit 1122 and within the paddle cavity 1140 of the bump paddle 1138. The first integrated circuit 1122 can be attached to the second electrical connectors 1148 of the first device 1152. A second encapsulation 1150, such as an underfill, can surround and provide structural support to the second electrical connectors 1148.

A second device 1153, such as passive component or a discrete component, can connect the first extension 1116 and the second extension 1160. The second device 1153 can provide frequency filtering, reference setting, or mode setting to the first integrated circuit 1122.

The leads 1136 can extend from the non-horizontal sides of the encapsulation 1102. As an example, the leads 1136 are shown bending towards the first encapsulation side 1104. As a different example (not shown), the leads 1136 can bend towards the second encapsulation side 1106.

The encapsulation 1102 can cover the first integrated circuit 1122, the second integrated circuit 1126, the first device 1152, the second device 1153, the first internal interconnects 1130, the second internal interconnects 1132, and the third internal interconnects 1134. The first encapsulation side 1104 can expose the bump paddle 1138, the first terminals 1108, and the second terminals 1110. For example, the bump paddle 1138, the first terminals 1108, and the second terminals 1110 can be formed in a U-shaped terminal in a non-planar configuration extending below the first encapsulation side 1104. For illustrative purposes, the bump paddle 1138, the first terminals 1108, and the second terminals 1110 are shown as U-shaped terminals, although it is understood that it can be of different geometric shapes, such as rectangular, triangular, or circular shapes.

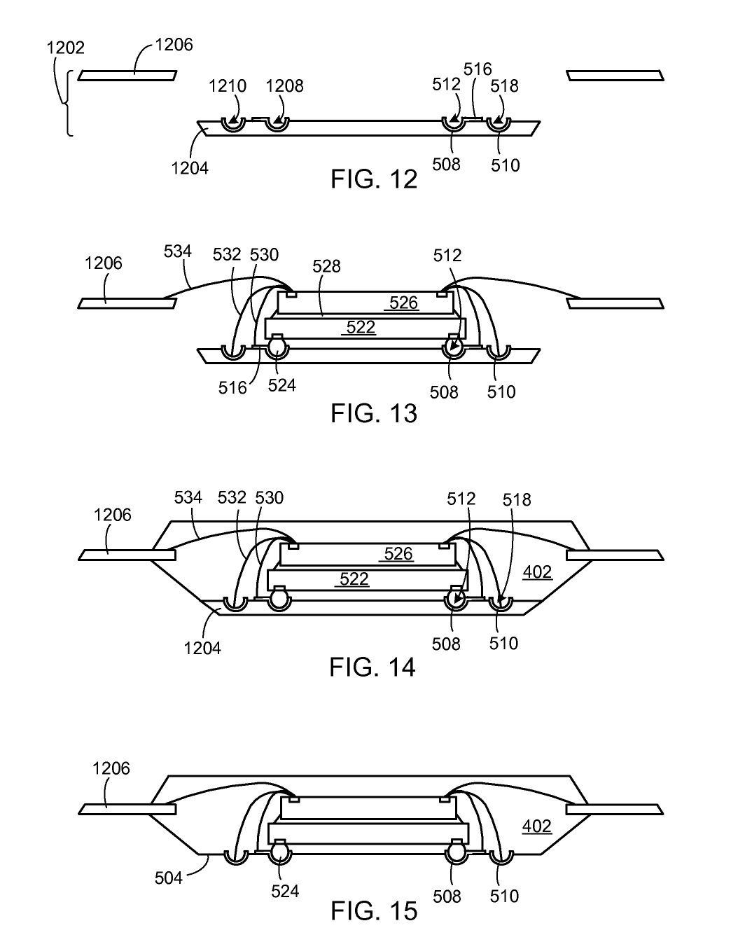

Referring now to FIG. 12, therein is shown a structure of a portion of a lead frame 1202. The cross-sectional view depicts a paddle 1204 such as a copper paddle, between internal connectors 1206. The paddle 1204 includes first recesses 1208 and second recesses 1210.

The first terminals 508 can be formed over the first recesses 1208. The second terminals 510 can be formed over the second recesses 1210. The first terminals 508 are shown having the first cavity 512, and the first extension 516 at a periphery of the first terminals 508. The second terminals 510 are adjacent to the first terminals 508. The second terminals 510 are shown having the second cavity 518. As an example, the internal connectors 1206 are shown non-planar with the paddle 1204.

Referring now to FIG. 13, therein is shown the structure of FIG. 14 in a connecting phase of the first integrated circuit 522 and the second integrated circuit 526. The first integrated circuit 522 can be over the first terminals 508 with the first electrical connectors 524 attached within the first cavity 512 of the first terminals 508. The second integrated circuit 526 is over the first integrated circuit 522 with the adhesive 528.

The First internal interconnects 530 can be between the second integrated circuit 526 and the first extension 516 of the first terminals 508. The second internal interconnects 532 can be between the second integrated circuit 526 and the second terminals 510. The third internal interconnects 534 can be between the second integrated circuit 526 and the internal connectors 1206.

Referring now to FIG. 14, therein is shown the structure of FIG. 13 in a forming the encapsulation 402. The encapsulation 402 can be injected molded over the first integrated circuit 522, the second integrated circuit 526, the interior portion of the internal connectors 1206, the first internal interconnects 530, the second internal interconnects 532 and the third internal interconnects 534.

The paddle 1204 bounds the molding process. The encapsulation 402 fills the first cavity 512 of the first terminals 508, and the second cavity 518 of the second terminals 510. The internal connectors 1206 can extend from the non-horizontal sides of the encapsulation 402.

Referring now to FIG. 15, therein is shown the structure of FIG. 14 in forming the integrated circuit packaging system 400 of FIG. 5. The structure of FIG. 15 undergoes a removal process, such as etching, for removing the paddle 1204 of FIG. 14 from the encapsulation 402. The removal process exposes the first terminals 508, and the second terminals 510. The removal process also exposes the first encapsulation side 504. The structure can undergo singulation and forming or bending to shape the internal connectors 1206 to the first electrical connectors 524 of FIG. 5.

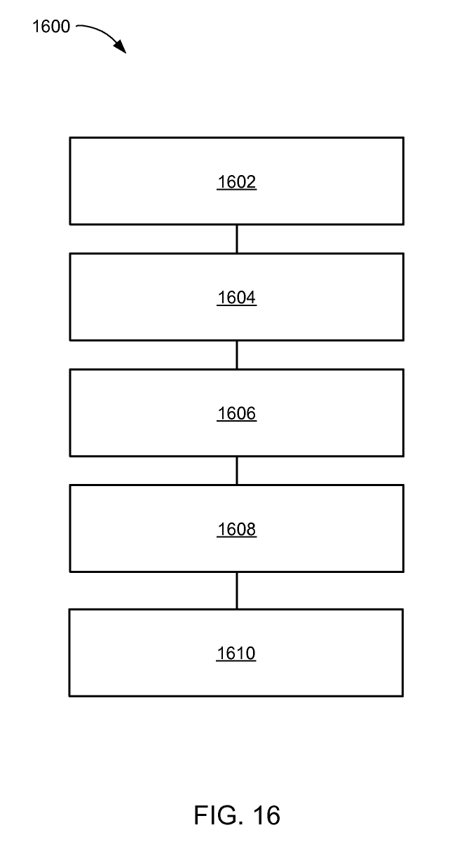

Referring now to FIG. 16, therein is shown a flow chart of a method 1600 of manufacture of the integrated circuit packaging system 100 in a further embodiment of the present invention. The method 1600 includes forming a first terminal having a cavity in a block 1602; mounting a first integrated circuit over the first terminal and connected in the cavity in a block 1604; forming a second terminal adjacent to the first terminal in a block 1606; connecting a second integrated circuit, over the first integrated circuit, and the second terminal in a block 1608; and forming a first encapsulation over the first integrated circuit with the first terminal exposed in a block 1610.

Yet other important aspects of the embodiments include that it valuably supports and services the historical trend of reducing costs, simplifying systems, and increasing performance.

These and other valuable aspects of the embodiments consequently further the state of the technology to at least the next level.

Thus, it has been discovered that the integrated circuit packaging system of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
forming a first terminal having a cavity;
mounting a first integrated circuit over the first terminal and connected in the cavity;
forming a second terminal adjacent to the first terminal;
connecting a second integrated circuit, over the first integrated circuit, and the second terminal; and
forming a first encapsulation over the first integrated circuit with the first terminal exposed.

2. The method as claimed in claim 1 wherein forming the first encapsulation includes covering the first integrated circuit and the second integrated circuit with the second terminal exposed.

3. The method as claimed in claim 1 further comprising:
forming a lead;
connecting the second integrated circuit and the lead; and wherein forming the encapsulation includes:
covering an upper portion of the lead; and
exposing a lower portion of the lead.

4. The method as claimed in claim 1 further comprising:
mounting a device under the first integrated circuit and in the cavity; and
forming a second encapsulation under the first integrated circuit with the cavity filled.

5. The method as claimed in claim 1 wherein:
forming the first terminal having the cavity includes forming a bump paddle having paddle cavity; and
further comprising:
mounting a device to the first integrated circuit with the device over the paddle cavity.

6. A method of manufacture of an integrated circuit packaging system comprising:
forming a first terminal having a cavity;
mounting a first integrated circuit, having an electrical connector, over a first terminal and the electrical connector within the cavity;
forming a second terminal adjacent to the first terminal;
mounting a second integrated circuit over the first integrated circuit;
connecting the second integrated circuit and the second terminal; and
forming a first encapsulation over the first integrated circuit and the second integrated circuit with the first terminal exposed.

7. The method as claimed in claim 6 further comprising connecting the second integrated circuit and the first terminal.

8. The method as claimed in claim 6 wherein forming the second terminal includes forming a planar lead.

9. The method as claimed in claim 6 further comprising connecting the first integrated circuit and the second terminal.

10. The method as claimed in claim 6 further comprising connecting a device between the first terminal and the second terminal.

11. An integrated circuit packaging system comprising:
a first terminal having a cavity;
a first integrated circuit over the first terminal and connected in the cavity;
a second terminal adjacent to the first terminal;
a second integrated circuit over the first integrated circuit and connected to the second terminal; and
a first encapsulation over the first integrated circuit with the first terminal exposed.

12. The system as claimed in claim 11 wherein the first encapsulation over the first integrated circuit and the second integrated circuit with the second terminal exposed.

13. The system as claimed in claim 11 further comprising:
a lead;
wherein:
the second integrated circuit connected to the lead; and
the encapsulation covered an upper portion of the lead and exposed a lower portion of the lead.

14. The system as claimed in claim 11 further comprising:
a device under the first integrated circuit and in the cavity; and
a second encapsulation under the first integrated circuit with the cavity filled.

15. The system as claimed in claim 11 wherein:
the first terminal having the cavity includes a bump paddle having a paddle cavity; and
further comprising:
a device mounted to the first integrated circuit with the device over the paddle cavity.

16. The system as claimed in claim 11 wherein:
the first integrated circuit includes an electrical connector within the cavity; and
the first encapsulation over the second integrated circuit.

17. The system as claimed in claim 16 further comprising the second integrated circuit connected to the first terminal.

18. The system as claimed in claim 16 wherein the second terminal includes a planar lead.

19. The system as claimed in claim 16 wherein the first integrated circuit connected to the second terminal.

20. The system as claimed in claim 16 further comprising a device between the first terminal and the second terminal.
